(19) United States
(12) Patent Application Publication
(10) Pub. No.: US 2025/0298315 A1
(43) Pub. Date: Sep. 25, 2025

(54) PHOTOSENSITIVE RESIN COMPOSITION, PHOTOSENSITIVE RESIN COATING, PHOTOSENSITIVE DRY FILM, AND PATTERN FORMING PROCESS

(71) Applicant: Shin-Etsu Chemical Co., Ltd., Tokyo (JP)

(72) Inventors: Hitoshi Maruyama, Annaka-shi (JP); Yugo Kawaguchi, Annaka-shi (JP)

(73) Assignee: Shin-Etsu Chemical Co., Ltd., Tokyo (JP)

(21) Appl. No.: 19/083,789

(22) Filed: Mar. 19, 2025

(30) Foreign Application Priority Data
Mar. 25, 2024 (JP) 2024-047468

(51) Int. Cl. G03F 7/075; G03F 7/004; G03F 7/40

(52) U.S. Cl. CPC G03F 7/0757; G03F 7/0045; G03F 7/40

(57) ABSTRACT

The photosensitive resin composition includes (A) a polymer having a silphenylene skeleton, a polysiloxane skeleton, and a fluorene skeleton in a main chain, and containing a polyhydric alcohol structure in a side chain, (B) a crosslinker of specific structure, and (C) a photoacid generator. The photosensitive resin composition gives a resin coating or resin layer that can be simply processed in thick film form to define a fine size perpendicular pattern.

### CROSS-REFERENCE TO RELATED APPLICATIONS

This non-provisional application claims priority under 35 U.S.C. § 119 (a) on Patent Application No. 2024-047468 filed in Japan on Mar. 25, 2024, the entire contents of which are hereby incorporated by reference.

### TECHNICAL FIELD

This invention relates to a photosensitive resin composition, photosensitive resin coating, photosensitive dry film, and pattern forming process.

### BACKGROUND ART

In the prior art, photosensitive protective films for semiconductor devices and photosensitive insulating films for multilayer printed circuit boards are formed of photosensitive polyimide compositions, photosensitive epoxy resin compositions, photosensitive silicone compositions, and the like. As the photosensitive material applied for the protection of such substrates and circuits, Patent Document 1 discloses a photosensitive silicone composition having improved flexibility. This photosensitive silicone composition is curable at low temperature and forms a coating which is fully reliable with respect to moisture resistant adhesion and other properties, but suffers from poor resistance against chemicals such as photoresist strippers, typically N-methyl-2-pyrrolidone.

To overcome the problem, Patent Document 2 proposes a photosensitive silicone composition based on a silphenylene skeleton-containing silicone polymer. This photosensitive silicone composition is improved in chemical resistance against conventional photoresist strippers such as N-methyl-2-pyrrolidone, but still has a problem in chemical resistance against photoresist strippers having a higher dissolving power. In addition, there are demands for further improvement also in the level of fine pattern formation and in the reliability of resin coatings.

### CITATION LIST

Patent Document 1: JP-A 2002-88158
Patent Document 2: JP-A 2008-184571

### SUMMARY OF THE INVENTION

An object of the invention, which has been made under the above-mentioned circumstances, is to provide a photosensitive resin composition, photosensitive resin coating, and photosensitive dry film, which give a resin coating or resin layer that can be simply processed in thick film form to define a fine size perpendicular pattern, and provide a cured coating excellent in copper migration resistance, photoresist stripper resistance, adhesion to substrates or the like, and heat resistance, and excellent in reliability as a protective film for electric and electronic parts and a film for bonding substrates, and a pattern forming process using the foregoing.

Making extensive investigations to attain the above object, the inventors have found that the object can be attained by a photosensitive resin composition comprising: (A) a polymer having a silphenylene skeleton, a polysiloxane skeleton, and a fluorene skeleton in a main chain, and containing a polyhydric alcohol structure in a side chain; (B) at least one crosslinker selected from among a nitrogen-containing compound selected from melamine, guanamine, glycoluril, and urea compounds, having on the average at least two methylol and/or alkoxymethyl groups per molecule, an amino condensate modified with formaldehyde or formaldehyde-alcohol, and a phenol compound having on the average at least two methylol or alkoxymethyl groups per molecule; and (C) a photoacid generator. The invention is predicated on this finding.

That is, this invention provides the following photosensitive resin composition, photosensitive resin coating, photosensitive dry film, and pattern forming process.

1. A photosensitive resin composition comprising:
(A) a polymer having a silphenylene skeleton, a polysiloxane skeleton, and a fluorene skeleton in a main chain, and containing a polyhydric alcohol structure in a side chain;
(B) at least one crosslinker selected from among a nitrogen-containing compound selected from melamine, guanamine, glycoluril, and urea compounds, having on the average at least two methylol and/or alkoxymethyl groups per molecule, an amino condensate modified with formaldehyde or formaldehyde-alcohol, and a phenol compound having on the average at least two methylol or alkoxymethyl groups per molecule; and
(C) a photoacid generator.

2. The photosensitive resin composition according to 1, wherein polymer (A) includes a repeat unit having formula (A1) and a repeat unit having formula (A2), and may further include a repeat unit having formula (A3) and a repeat unit having formula (A4):

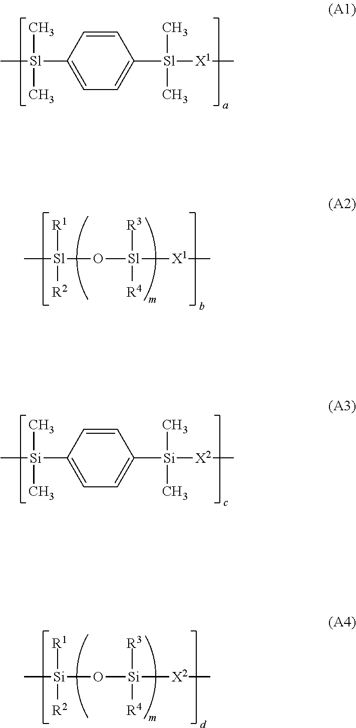

wherein R¹ to R⁴ are each independently a hydrocarbyl group that has 1 to 20 carbon atoms and may contain a heteroatom, m is each independently an integer of 1 to 600, and when m is an integer of 2 or more, R³s may be identical with or different from each other, and R⁴s may be identical with or different from each other, a, b, c, and d are numbers satisfying 0<a<1, 0<b<1, 0≤c<1, 0≤d<1, and a+b+c+d=1, X¹ is a divalent group having formula (X1), and X2 is a divalent group having formula (X2);

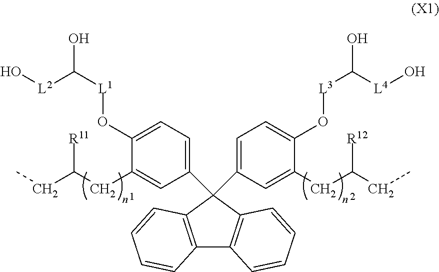

wherein n¹ and n² are each independently an integer of 1 to 7, R¹¹ and R¹² are each independently a hydrogen atom or a methyl group, L¹ to L⁴ are each independently a saturated hydrocarbylene group having 1 to 15 carbon atoms, a part of —CH₂— of the saturated hydrocarbylene groups may be substituted with —O—, —S—, —SO₂—, —CO—, or —CONH—, and a part or all of hydrogen atoms of the saturated hydrocarbylene groups may be substituted with a hydroxy group, and a broken line designates a bond; and

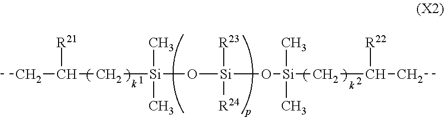

wherein R²¹ and R²² are each independently a hydrogen atom or a methyl group, R²³ and R²⁴ are each independently a hydrocarbyl group having 1 to 8 carbon atoms, k¹ and k² are each independently an integer of 0 to 7, p is an integer of 0 to 600, and a broken line designates a bond.

3. The photosensitive resin composition according to 2, wherein all of L¹, L², L³, and L⁴ have 1 carbon atom.

4. The photosensitive resin composition according to any one of 1 to 3, wherein the content of the compound as component (B) is 1 to 50 parts by weight per 100 parts by weight of component (A).

5. The photosensitive resin composition according to any one of 1 to 4, further comprising (D) a solvent.

6. A photosensitive resin coating obtained from the photosensitive resin composition according to any one of 1 to 5.

7. A photosensitive dry film comprising a support film and the photosensitive resin coating according to 6 thereon.

8. A pattern forming process comprising the steps of:
(i) applying the photosensitive resin composition according to any one of 1 to 5 onto a substrate to form a photosensitive resin coating thereon,
(ii) exposing the photosensitive resin coating to radiation, and
(iii) developing the exposed resin coating in a developer to form a pattern of the resin coating.

9. The pattern forming process according to 8, further comprising (iv) post-curing the patterned resin coating resulting from the development step at a temperature of 100 to 250° C.

10. A pattern forming process comprising the steps of:
(i′) using the photosensitive dry film according to 7 to form a photosensitive resin coating on a substrate,
(ii) exposing the photosensitive resin coating to radiation, and
(iii) developing the exposed resin coating in a developer to form a pattern of the resin coating.

11. The pattern forming process according to 10, further comprising (iv) post-curing the patterned resin coating resulting from the development step at a temperature of 100 to 250° C.

12. The photosensitive resin composition according to any one of 1 to 5 which is a material adapted to form a coating for protecting electric and electronic parts.

13. The photosensitive resin composition according to any one of 1 to 5 which is a material adapted to form a substrate-bonding coating for bonding two substrates.

### Advantageous Effects of the Invention

The photosensitive resin composition of the invention is able to form a coating having a widely varying range of thickness, and easy to form a small-size pattern in thick film form having improved perpendicularity by the pattern forming process defined herein. The cured coating obtained from the photosensitive resin composition and the photosensitive dry film of the invention has excellent photoresist stripper resistance, adhesion to substrates or the like, and heat resistance, and is improved in adhesion to substrates, specifically substrates for use in electronic parts and semiconductor devices, especially circuit boards, mechanical properties including crack resistance, and copper migration resistance. Also, the coating is fully reliable as an insulating protective film and advantageously used as a material adapted to form a protective film for protecting electric and electronic parts such as circuit boards, semiconductor devices, and display devices, and a material adapted to form a film for bonding substrates.

### DETAILED DESCRIPTION OF THE INVENTION

### [Photosensitive Resin Composition]

The invention provides a photosensitive resin composition comprising (A) a polymer having a silphenylene skeleton, a polysiloxane skeleton, and a fluorene skeleton in a main chain, and containing a polyhydric alcohol structure in a side chain, (B) a crosslinker of specific structure, and (C) a photoacid generator.

### [(A) Polymer Having Silphenylene Skeleton, Polysiloxane Skeleton, and Fluorene Skeleton in Main Chain, and Containing Polyhydric Alcohol Structure in Side Chain]

The polymer as component (A) is preferably a polymer that contains a repeat unit having formula (A1) and a repeat unit having formula (A2), and may further contain a repeat unit having formula (A3) and a repeat unit having formula (A4).

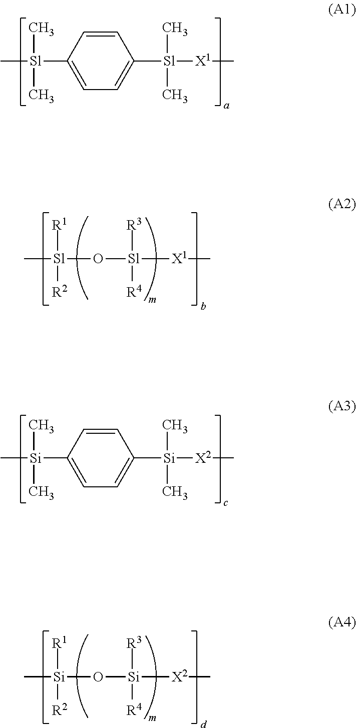

In formulae (A1) to (A4), a, b, c, and d are numbers satisfying 0<a<1, 0<b<1, 0≤c<1, 0≤d<1, and a+b+c+d=1, and are preferably numbers satisfying 0.1<a<0.8, 0.1<b<0.8, 0≤c<0.15, 0≤d<0.15, and a+b+c+d=1.

In formulae (A2) and (A4), R¹ to R⁴ are each independently a hydrocarbyl group that has 1 to 20 carbon atoms and may contain a heteroatom. m is each independently an integer of 1 to 600, and is preferably an integer of 8 to 100. When m is an integer of 2 or more, R³s may be identical with or different from each other, and R⁴s may be identical with or different from each other.

In each of formulae (A2) and (A4), when there are two or more siloxane units (that is, when m is an integer of 2 or more), all the siloxane units may be identical with each other, or the repeat unit of formula (A2) or (A4) may contain two or more types of different siloxane units. When the repeat unit of formula (A2) or (A4) contains two or more types of different siloxane units, the siloxane units may be randomly bonded or alternately bonded, or the repeat unit of formula (A2) or (A4) may contain a plurality of blocks of the same type of siloxane units.

In formulae (A1) and (A2), X¹ is a divalent group having formula (X1). The divalent group having formula (X1) is a group having a fluorene skeleton.

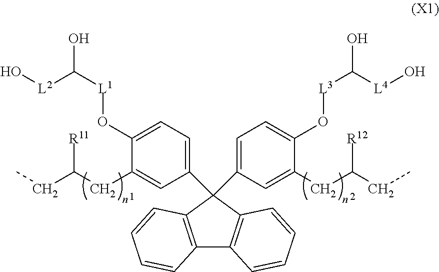

In the formula, a broken line designates a bond.

In formula (X1), n¹ and n² are each independently an integer of 1 to 7, and are each preferably 1.

In formula (X1), R¹¹ and R¹² are each independently a hydrogen atom or a methyl group, and both of R¹¹ and R¹² are preferably a hydrogen atom.

In formula (X1), L¹ to L⁴ are each independently a saturated hydrocarbylene group having 1 to 15 carbon atoms, a part of —CH₂— of the saturated hydrocarbylene groups may be substituted with —O—, —S—, —SO₂—, —CO—, or —CONH—, and a part or all of hydrogen atoms of the saturated hydrocarbylene groups may be substituted with a hydroxy group. The —CH₂— of the saturated hydrocarbylene group may be located at a terminal thereof.

The saturated hydrocarbylene group may be linear, branched, or cyclic, and specific examples thereof include alkanediyl groups having 1 to 15 carbon atoms, such as a methanediyl group, an ethane-1,1-diyl group, an ethane-1,2-diyl group, a propane-1,3-diyl group, a butane-1,4-diyl group, a pentane-1,5-diyl group, a hexane-1,6-diyl group, a heptane-1,7-diyl group, an octane-1,8-diyl group, a nonane-1,9-diyl group, a decane-1,10-diyl group, an undecane-1,11-diyl group, a dodecane-1,12-diyl group, a tridecane-1,13-diyl group, a tetradecane-1,14-diyl group, and a pentadecane-1,15-diyl group; and cyclic saturated hydrocarbylene groups having 3 to 15 carbon atoms, such as a cyclopentanediyl group, a cyclohexanediyl group, a norbornanediyl group, and an adamantanediyl group.

It is preferable that both of L¹ and L³ have 1 carbon atom, and it is more preferable that both of L² and L⁴ have 1 carbon atom.

In formulae (A3) and (A4), X² is a divalent group having formula (X2).

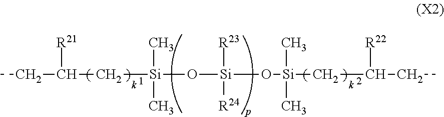

In the formula, a broken line designates a bond.

In formula (X2), R²¹ and R²² are each independently a hydrogen atom or a methyl group, and are each preferably a hydrogen atom.

In formula (X2), R²³ and R²⁴ are each independently a hydrocarbyl group having 1 to 8 carbon atoms.

In formula (X2), k¹ and k² are each independently an integer of 0 to 7, and are each preferably 0.

In formula (X2), p is an integer of 0 to 600, preferably an integer of 0 to 100, and more preferably an integer of 0 to 30. When p is an integer of 2 or more, R²³s may be identical with or different from each other, and R²⁴s may be identical with or different from each other.

The polymer as component (A) preferably has a weight average molecular weight (Mw) of 2,000 to 500,000, and more preferably 8,000 to 100,000. A polymer having a Mw in the above-mentioned range can be obtained in the form of a solid, and the film formability can also be ensured. In the present invention, the Mw is a value measured in terms of polystyrene by gel permeation chromatography (GPC) using tetrahydrofuran (THF) as an elution solvent.

The polymer as component (A) may be one in which the repeat unit having formula (A1), the repeat unit having formula (A2), the repeat unit having formula (A3), and the repeat unit having formula (A4) are randomly bonded or alternately bonded, or may contain a plurality of blocks of each unit.

The polymer as component (A) functions as one that imparts film-forming ability. The obtained resin film has good pattern-forming ability, and the obtained cured film has good adhesion to a substrate or the like, crack resistance, chemical resistance, and heat resistance.

The polymer as component (A) may be used singly or in combination of two or more types thereof.

The method for producing the polymer as component (A) is not particularly limited, and for example, the polymer can be produced by addition polymerization of a compound having formula (1), a compound having formula (2), a compound having formula (3), and if necessary, a compound having formula (4) in the presence of a metal catalyst.

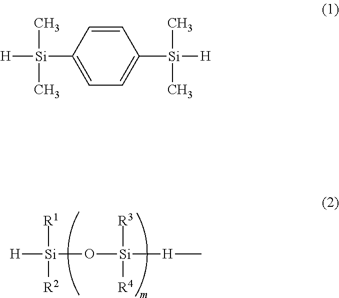

In the formula, R¹ to R⁴ and m are as defined above.

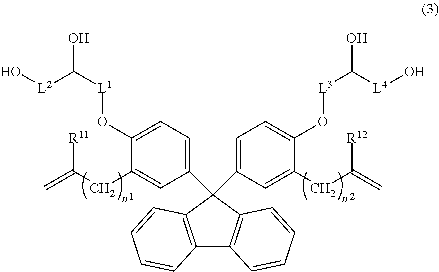

In the formula, R¹¹ and R¹², n¹, n², and L¹ to L⁴ are as defined above.

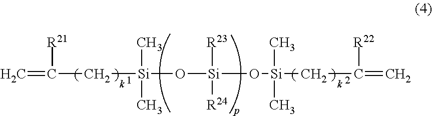

In the formula, R²¹ to R²⁴, k¹, k², and p are as defined above.

As for the metal catalyst, the following catalysts can be used: simple substances of platinum group metals, such as platinum (including platinum black), rhodium, and palladium; platinum chlorides, chloroplatinic acids, and chloroplatinates, such as H₂PtCl₄·xH₂O, H₂PtCl₆·xH₂O, NaHPtCl₆·xH₂O, KHPtCl₆·xH₂O, Na₂PtCl₆·xH₂O, K₂PtCl₄·xH₂O, PtCl₄·xH₂O, PtCl₂, and Na₂HPtCl₄·xH₂O (wherein x is preferably an integer of 0 to 6, and particularly preferably 0 or 6); alcohol-modified chloroplatinic acids (for example, those described in U.S. Pat. No. 3,220,972); complexes of a chloroplatinic acid with an olefin (for example, those described in U.S. Pat. Nos. 3,159,601, 3,159,662, and 3,775,452); platinum group metals such as platinum black and palladium supported on a carrier such as alumina, silica, or carbon; rhodium-olefin complexes;

chlorotris(triphenylphosphine) rhodium (so-called Wilkinson's catalyst); and complexes of a platinum chloride, a chloroplatinic acid, or a chloroplatinate with a vinyl group-containing siloxane (in particular, a vinyl group-containing cyclosiloxane).

The amount of the catalyst used is a catalytic amount, and is usually preferably 0.001 to 0.1 wt % in terms of a platinum group metal with respect to the total amount of the reaction polymer. In the polymerization reaction, a solvent may be used if necessary. The solvent is, for example, preferably a hydrocarbon solvent such as toluene or xylene. As for the conditions of the polymerization, from the viewpoint of inhibiting the deactivation of the catalyst and completing the polymerization in a short time, the polymerization temperature is, for example, preferably 40 to 150° C., and particularly preferably 60 to 120° C. The polymerization time depends on the type and amount of the polymer, but is preferably about 0.5 to 100 hours, and particularly preferably 0.5 to 30 hours in order to inhibit interference of moisture in the polymerization system. After completion of the polymerization reaction, the solvent, when being used, is distilled off to give the polymer.

The reaction method is not particularly limited, but it is preferable to first mix and heat the compound having formula (2), the compound having formula (3), and if necessary, the compound having formula (4), then add the metal catalyst to the resulting mixed solution, and then add the compound having formula (1) dropwise to the mixed solution over 0.1 to 5 hours.

These raw material compounds are preferably blended so that the total amount of hydrosilyl groups in the compound having formula (1) and the compound having formula (2) is 0.67 to 1.67, and more preferably 0.83 to 1.25 in terms of molar ratio with respect to the total amount of alkenyl groups in the compound having formula (3) and the compound having formula (4). The Mw of the polymer of the present invention can be controlled by using a monoallyl compound such as o-allylphenol, or a monohydrosilane or a monohydrosiloxane such as triethylhydrosilane as a molecular weight modifier.

In the polymerization reaction, a polymerization inhibitor may be optionally used. Examples of the polymerization inhibitor used include various phenols, hydroquinones, benzoquinones, catechols, hydroxylamines, and nitroso compounds. The amount of the polymerization inhibitor used is not particularly limited, but is preferably 0.001 to 10 wt %, and more preferably 0.01 to 5 wt % with respect to the compound having formula (3).

After completion of the reaction, a solvent is optionally added, and water washing is performed. Then, the solvent is distilled off by heating the organic layer under reduced pressure to give the polymer as component (A). At the time of water washing, an aqueous solution of a metal hydroxide such as sodium hydroxide or potassium hydroxide, or a metal carbonate or a metal hydrogen carbonate such as sodium carbonate, sodium hydrogen carbonate, or potassium carbonate may be optionally used.

Another example of the method for producing the polymer as component (A) is a reaction between a polymer that contains a repeat unit having formula (B1) and a repeat unit having formula (B2), and may further contain a repeat unit having formula (B3) and a repeat unit having formula (B4) (hereinafter, the polymer is also referred to as a polymer (B) and a compound having formula (5).

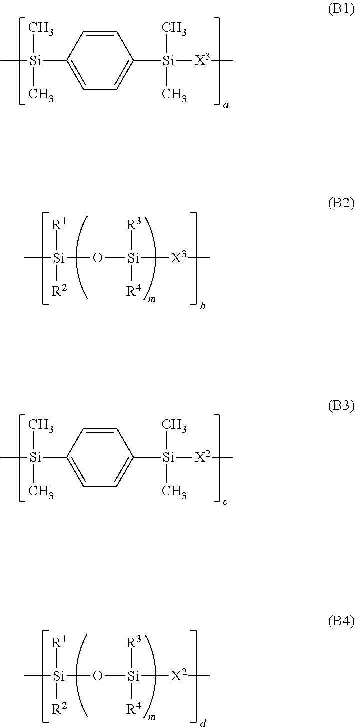

In the formulae, R¹ to R⁴, m, a, b, c, d, and X² are as defined above.

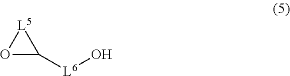

In formulae (B1) and (B2), X³ is a divalent group having formula (X3). The divalent group having formula (X3) is a group having a fluorene skeleton.

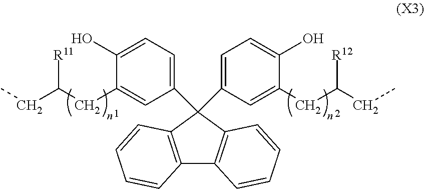

In the formula, R¹¹, R¹², n¹, and n² are as defined above. A broken line designates a bond.

In formula (5), L⁵ is a saturated hydrocarbylene group having 1 to 14 carbon atoms, a part of —CH₂— of the saturated hydrocarbylene group may be substituted with —O—, —S—, —SO₂—, —CO—, or —CONH—, and a part or all of hydrogen atoms of the saturated hydrocarbylene group may be substituted with a hydroxy group. The saturated hydrocarbylene group represented by L⁵ may be linear, branched, or cyclic, and preferably has 1 to 7 carbon atoms.

In formula (5), L⁶ is a saturated hydrocarbylene group having 1 to 14 carbon atoms, a part of —CH₂— of the saturated hydrocarbylene group may be substituted with —O—, —S—, —SO₂—, —CO—, or —CONH—, and a part or all of hydrogen atoms of the saturated hydrocarbylene group may be substituted with a hydroxy group. The saturated hydrocarbylene group represented by L⁵ may be linear, branched, or cyclic, and preferably has 1 to 7 carbon atoms.

Specific examples of the compound having formula (5) include glycidol (Epiol OH® manufactured by NOF CORPORATION), but are not limited thereto.

The reaction conditions are not particularly limited, but it is usually preferable to mix and heat the polymer B and the compound having formula (5) in a solvent. From the viewpoint of accelerating the reaction, a polar solvent is preferably used as the solvent, and an alcohol-based solvent such as propylene glycol monomethyl ether is particularly preferably used. From the viewpoint of inhibiting side reactions and completing the reaction in a short time, the reaction temperature is, for example, preferably 35 to 130° C., and particularly preferably 45 to 100° C. The reaction time depends on the type and amount of the reaction substrate, but is preferably about 0.5 to 50 hours, and particularly preferably 0.5 to 24 hours.

In the above-mentioned reaction, the raw material compounds are blended such that the molar ratio of the compound having formula (5) to X³ in the polymer B is preferably 1.0 to 8.0, and more preferably 4.0 to 6.0. The compound having formula (5) may be used singly or in combination of two or more types thereof.

In the above-mentioned reaction, a catalyst may be optionally used. Examples of the catalyst include amines such as triethylamine, triethylenediamine, bis-(2-dimethylaminoethyl) ether, and N-methylmorpholine; phosphines such as triphenylphosphine and tri (o-tolyl)phosphine; quaternary ammonium salts such as tetrabutylammonium chloride, benzyltriethylammonium chloride, and tetraethylhydroxylammonium; imidazole compounds such as imidazole and 2-ethyl-4-methylimidazole; pyridine compounds such as pyridine, N,N-dimethyl-4-aminopyridine, and 2,6-lutidine; organotin compounds such as tin acetate, tin octylate, tin oleate, tin laurate, dibutyltin diacetate, dimethyltin dilaurate, dibutyltin dilaurate, dibutyltin dimercaptide, dibutyltin maleate, dibutyltin dilaurate (dibutyltin (IV) dilaurate), dibutyltin dineodecanoate, dioctyltin dimercaptide, dioctyltin dilaurylate, and dibutyltin dichloride; organolead compounds such as lead octanoate and lead naphthenate; organonickel compounds such as nickel naphthenate; organocobalt compounds such as cobalt naphthenate; organocopper compounds such as copper octenate; organobismuth compounds such as bismuth octylate and bismuth neodecanoate; and potassium salts such as potassium carbonate, potassium acetate, and potassium octylate.

The amount of the catalyst used is usually a catalytic amount, and is preferably 0.1 to 20 mol % with respect to X³ in the polymer B. The catalyst may be used singly or in combination of two or more types thereof.

In the above-mentioned reaction, a polymerization inhibitor may be optionally used. Examples of the polymerization inhibitor used include various phenols, hydroquinones, benzoquinones, catechols, hydroxylamines, and nitroso compounds. The amount of the polymerization inhibitor used is not particularly limited, but is preferably 0.001 to 10 wt %, and more preferably 0.01 to 5 wt % with respect to the compound having formula (3).

After completion of the reaction, a solvent is optionally added, and water washing is performed. Then, the solvent is distilled off by heating the organic layer under reduced pressure to give the polymer as component (A). At the time of water washing, an aqueous solution of a metal hydroxide such as sodium hydroxide or potassium hydroxide, or a metal carbonate or a metal hydrogen carbonate such as sodium carbonate, sodium hydrogen carbonate, or potassium carbonate may be optionally used.

### [(B) Crosslinker]

The crosslinker as component (B) is at least one crosslinker selected from among a nitrogen-containing compound selected from melamine, guanamine, glycoluril, and urea compounds, having on the average at least two methylol and/or alkoxymethyl groups per molecule, an amino condensate modified with formaldehyde or formaldehyde-alcohol, and a phenol compound having on the average at least two methylol or alkoxymethyl groups per molecule. The crosslinker is crosslinked with the polymer as component (A) to form a fine size perpendicular pattern in thick film form, and make a cured film having good adhesion to a substrate or the like, crack resistance, chemical resistance, and heat resistance.

Suitable melamine compounds include those having the formula (B1).

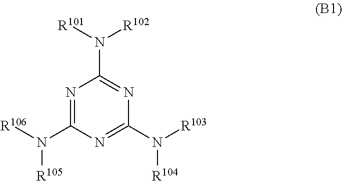

In formula (B1), R¹⁰¹ to R¹⁰⁶ are each independently a methylol group, C2-C5 saturated hydrocarbyloxymethyl group or hydrogen atom, at least one of R¹⁰¹ to R¹⁰⁶ being methylol or saturated hydrocarbyloxymethyl group. Suitable saturated hydrocarbyloxymethyl groups include alkoxymethyl groups such as methoxymethyl and ethoxymethyl.

Examples of the melamine compound having formula (B1) include trimethoxymethylmonomethylolmelamine, dimethoxymethylmonomethylolmelamine, trimethylolmelamine, hexamethylolmelamine, hexamethoxymethylmelamine, and hexaethoxymethylmelamine.

The melamine compound having formula (B1) may be obtained, for example, by modifying a melamine monomer with formaldehyde into a methylol form in a well-known manner, and optionally, further modifying it with an alcohol into an alkoxy form. The alcohols used herein are preferably lower alcohols, for example, alcohols having 1 to 4 carbon atoms.

Suitable guanamine compounds include tetramethylolguanamine, tetramethoxymethylguanamine and tetramethoxyethylguanamine.

Suitable glycoluril compounds include tetramethylolglycoluril and tetrakis(methoxymethyl)glycoluril.

Suitable urea compounds include tetramethylolurea, tetramethoxymethylurea, tetramethoxyethylurea, tetraethoxymethylurea, and tetrapropoxymethylurea.

Examples of the amino condensate modified with formaldehyde or formaldehyde-alcohol include melamine condensates modified with formaldehyde or formaldehyde-alcohol, and urea condensates modified with formaldehyde or formaldehyde-alcohol.

The modified melamine condensates are obtained, for example, by effecting addition polycondensation of a compound having formula (B1) or a polymer (e.g., oligomer such as dimer or trimer) thereof with formaldehyde until a desired molecular weight is reached. The addition polycondensation may be performed by any prior art well-known methods. The modified melamine having formula (B1) may be used alone or in admixture.

Examples of the urea condensate modified with formaldehyde or formaldehyde-alcohol include methoxymethylated urea condensates, ethoxymethylated urea condensates, and propoxymethylated urea condensates.

The modified urea condensates are prepared, for example, by modifying a urea condensate having a desired molecular weight with formaldehyde into a methylol form in a well-known manner, and optionally, further modifying it with an alcohol into an alkoxy form.

Examples of the phenol compound having on the average at least two methylol or alkoxymethyl groups in the molecule include (2-hydroxy-5-methyl)-1,3-benzenedimethanol and 2,2′,6,6′-tetramethoxymethylbisphenol A.

In the photosensitive resin composition, the content of component (B) is preferably 1 to 50 parts by weight, more preferably 1 to 30 parts by weight per 100 parts by weight of component (A). At least 1 part of component (B) ensures sufficient cure upon light exposure. As long as the amount of component (B) is up to 50 parts by weight, the proportion of component (A) in the photosensitive resin composition is not reduced, allowing the cured composition to exert its effects to the full extent. Component (B) may be used alone or in admixture.

### [(C) Photoacid Generator]

The photoacid generator as component (C) is not particularly limited as long as it is decomposed to generate an acid upon light exposure. A compound which is decomposed to generate an acid upon exposure to light of wavelength 190 to 500 nm is preferred. The PAG serves as a curing catalyst. Since the photosensitive resin composition of the invention is highly compatible with the PAG, the PAG may be selected from a wide variety of such compounds.

Suitable PAGs include onium salts, diazomethane derivatives, glyoxime derivatives, β-ketosulfone derivatives, disulfone derivatives, nitrobenzyl sulfonate derivatives, sulfonic acid ester derivatives, imido-yl-sulfonate derivatives, oxime sulfonate derivatives, and imino sulfonate derivatives.

Exemplary onium salts include sulfonium salts having the formula (C1) and iodonium salts having the formula (C2).

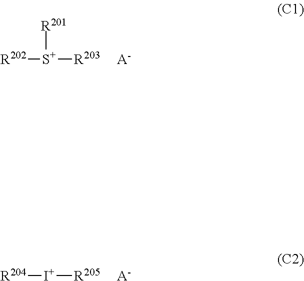

In formulae (C1) and (C2), R²⁰¹ to R²⁰⁵ are each independently an optionally substituted C1-C12 saturated hydrocarbyl group, an optionally substituted C6-C12 aryl group, or an optionally substituted C7-C12 aralkyl group. A⁻ is a non-nucleophilic counter ion.

The saturated hydrocarbyl group may be straight, branched or cyclic. Examples thereof include alkyl groups such as methyl, ethyl, propyl, butyl, pentyl, hexyl, and structural isomers thereof; and cyclic saturated hydrocarbyl groups such as cyclopropyl, cyclobutyl, cyclopentyl, cyclohexyl, norbornyl and adamantyl. The aryl groups include phenyl, naphthyl and biphenylyl. The aralkyl groups include benzyl and phenethyl.

Suitable substituents include oxo, C1-C12 saturated hydrocarbyl groups, C1-C12 saturated hydrocarbyloxy groups, C6-C24 aryl groups, C7-C25 aralkyl groups, C6-C24 aryloxy groups, and C6-C24 arylthio groups. Notably, the saturated hydrocarbyl group and hydrocarbyl moiety in the saturated hydrocarbyloxy group may be straight, branched or cyclic, and examples thereof are as exemplified above for the saturated hydrocarbyl group R²⁰¹ to R²⁰⁵.

Preferred examples of R²⁰¹ to R²⁰⁵ include optionally substituted saturated hydrocarbyl groups such as methyl, ethyl, propyl, butyl, cyclohexyl, norbornyl, adamantyl and 2-oxocyclohexyl; optionally substituted aryl groups such as phenyl, naphthyl, biphenylyl, 2-, 3- or 4-methoxyphenyl, 2-, 3- or 4-ethoxyphenyl, 3- or 4-tert-butoxyphenyl, 2-, 3- or 4-methylphenyl, 2-, 3- or 4-ethylphenyl, 4-tert-butylphenyl, 4-butylphenyl, dimethylphenyl, terphenylyl, biphenylyloxyphenyl, and biphenylylthiophenyl; and optionally substituted aralkyl groups such as benzyl and phenethyl. Of these, optionally substituted aryl groups and optionally substituted aralkyl groups are more preferred.

Examples of the non-nucleophilic counter ion include halide ions such as chloride and bromide; fluoroalkanesulfonate ions such as triflate, 1,1,1-trifluoroethanesulfonate, and nonafluorobutanesulfonate; arylsulfonate ions such as tosylate, benzenesulfonate, 4-fluorobenzenesulfonate, and 1,2,3,4,5-pentafluorobenzenesulfonate; alkanesulfonate ions such as mesylate and butanesulfonate; fluoroalkanesulfonimide ions such as trifluoromethanesulfonimide; fluoroalkanesulfonylmethide ions such as tris(trifluoromethanesulfonyl) methide; borate ions such as tetrakisphenylborate and tetrakis(pentafluorophenyl) borate; and phosphate ions such as hexafluorophosphate and tris(pentafluoroethyl)trifluorophosphate.

Exemplary diazomethane derivatives include compounds having the formula (C3).

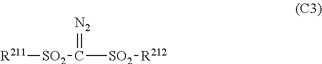

In formula (C3), R²¹¹ and R²¹² are each independently a C1-C12 saturated hydrocarbyl group, C1-C12 halogenated saturated hydrocarbyl group, optionally substituted C6-C12 aryl group, or C7-C12 aralkyl group.

The saturated hydrocarbyl group may be straight, branched or cyclic, and examples thereof are as exemplified above for the saturated hydrocarbyl groups R²⁰¹ to R²⁰⁵. Examples of the halogenated saturated hydrocarbyl group include trifluoromethyl, 1,1,1-trifluoroethyl, 1,1,1-trichloroethyl, and nonafluorobutyl.

Examples of the optionally substituted aryl group include phenyl; alkoxyphenyl groups such as 2-, 3- or 4-methoxyphenyl, 2-, 3- or 4-ethoxyphenyl, 3- or 4-tert-butoxyphenyl; alkylphenyl groups such as 2-, 3- or 4-methylphenyl, 2-, 3- or 4-ethylphenyl, 4-tert-butylphenyl, 4-butylphenyl, and dimethylphenyl; and halogenated aryl groups such as fluorophenyl, chlorophenyl, and 1,2,3,4,5-pentafluorophenyl. Examples of the aralkyl group include benzyl and phenethyl.

Examples of the onium salts include diphenyliodonium trifluoromethanesulfonate, (p-tert-butoxyphenyl)phenyliodonium trifluoromethanesulfonate, diphenyliodonium p-toluenesulfonate, (p-tert-butoxyphenyl)phenyliodonium p-toluenesulfonate, triphenylsulfonium trifluoromethanesulfonate, (p-tert-butoxyphenyl)diphenylsulfonium trifluoromethanesulfonate, bis(p-tert-butoxyphenyl)phenylsulfonium trifluoromethanesulfonate, tris(p-tert-butoxyphenyl)sulfonium trifluoromethanesulfonate, triphenylsulfonium p-toluenesulfonate, (p-tert-butoxyphenyl)diphenylsulfonium p-toluenesulfonate, bis(p-tert-butoxyphenyl)phenylsulfonium p-toluenesulfonate, tris(p-tert-butoxyphenyl) sulfonium p-toluenesulfonate, triphenylsulfonium nonafluorobutanesulfonate, triphenylsulfonium butanesulfonate, trimethylsulfonium trifluoromethanesulfonate, trimethylsulfonium p-toluenesulfonate, cyclohexylmethyl(2-oxocyclohexyl)sulfonium trifluoromethanesulfonate, cyclohexylmethyl(2-oxocyclohexyl)sulfonium p-toluenesulfonate, dimethylphenylsulfonium trifluoromethanesulfonate, dimethylphenylsulfonium p-toluenesulfonate, dicyclohexylphenylsulfonium trifluoromethanesulfonate, dicyclohexylphenylsulfonium p-toluenesulfonate, bis(4-tert-butylphenyl) iodonium hexafluorophosphate, 4-(phenylthio)phenyldiphenylsulfonium tris(pentafluoroethyl)trifluorophosphate, diphenyl(4-thiophenoxyphenyl)sulfonium hexafluoroantimonate, [4-(4-biphenylylthio)phenyl]-4-biphenylylphenylsulfonium tris(trifluoromethanesulfonyl) methide, triphenylsulfonium tetrakis(fluorophenyl) borate, tris [4-(4-acetylphenyl)thiophenyl]sulfonium tetrakis(fluorophenyl) borate, triphenylsulfonium tetrakis(pentafluorophenyl) borate, and tris [4-(4-acetylphenyl)thiophenyl]sulfonium tetrakis(pentafluorophenyl) borate.

Examples of the diazomethane derivatives include bis(benzenesulfonyl)diazomethane, bis(p-toluenesulfonyl)diazomethane, bis(xylenesulfonyl)diazomethane, bis(cyclohexylsulfonyl)diazomethane, bis(cyclopentylsulfonyl)diazomethane, bis(n-butylsulfonyl)diazomethane, bis(isobutylsulfonyl)diazomethane, bis(sec-butylsulfonyl)diazomethane, bis(n-propylsulfonyl)diazomethane, bis(isopropylsulfonyl)diazomethane, bis(tert-butylsulfonyl)diazomethane, bis(n-pentylsulfonyl)diazomethane, bis(isopentylsulfonyl)diazomethane, bis(sec-pentylsulfonyl)diazomethane, bis(tert-pentylsulfonyl)diazomethane, 1-cyclohexylsulfonyl-1-(tert-butylsulfonyl)diazomethane, 1-cyclohexylsulfonyl-1-(tert-pentylsulfonyl)diazomethane, and 1-tert-pentylsulfonyl-1-(tert-butylsulfonyl)diazomethane.

Examples of the glyoxime derivatives include bis-o-(p-toluenesulfonyl)-α-dimethylglyoxime, bis-o-(p-toluenesulfonyl)-α-diphenylglyoxime, bis-o-(p-toluenesulfonyl)-α-dicyclohexylglyoxime, bis-o-(p-toluenesulfonyl)-2,3-pentanedioneglyoxime, bis-o-(p-toluenesulfonyl)-2-methyl-3,4-pentanedioneglyoxime, bis-o-(n-butanesulfonyl)-α-dimethylglyoxime, bis-o-(n-butanesulfonyl)-α-diphenylglyoxime, bis-o-(n-butanesulfonyl)-α-dicyclohexylglyoxime, bis-o-(n-butanesulfonyl)-2,3-pentanedioneglyoxime, bis-o-(n-butanesulfonyl)-2-methyl-3,4-pentanedioneglyoxime, bis-o-(methanesulfonyl)-α-dimethylglyoxime, bis-o-(trifluoromethanesulfonyl)-α-dimethylglyoxime, bis-o-(1,1,1-trifluoroethanesulfonyl)-α-dimethylglyoxime, bis-o-(tert-butanesulfonyl)-α-dimethylglyoxime, bis-o-(perfluorooctanesulfonyl)-α-dimethylglyoxime, bis-o-(cyclohexanesulfonyl)-α-dimethylglyoxime, bis-o-(benzenesulfonyl)-α-dimethylglyoxime, bis-o-(p-fluorobenzenesulfonyl)-α-dimethylglyoxime, bis-o-(p-tert-butylbenzenesulfonyl)-α-dimethylglyoxime, bis-o-(xylenesulfonyl)-α-dimethylglyoxime, and bis-o-(camphorsulfonyl)-α-dimethylglyoxime.

Examples of the β-ketosulfone derivatives include 2-cyclohexylcarbonyl-2-(p-toluenesulfonyl) propane and 2-isopropylcarbonyl-2-(p-toluenesulfonyl) propane.

Examples of the disulfone derivatives include diphenyl disulfone and dicyclohexyl disulfone.

Examples of the nitrobenzyl sulfonate derivatives include 2,6-dinitrobenzyl p-toluenesulfonate and 2,4-dinitrobenzyl p-toluenesulfonate.

Examples of the sulfonic acid ester derivatives include 1,2,3-tris(methanesulfonyloxy)benzene, 1,2,3-tris(trifluoromethanesulfonyloxy)benzene, and 1,2,3-tris(p-toluenesulfonyloxy)benzene.

Examples of the imido-yl-sulfonate derivatives include phthalimido-yl-triflate, phthalimido-yl-tosylate, 5-norbornene-2,3-dicarboxyimido-yl-triflate, 5-norbornene-2,3-dicarboxyimido-yl-tosylate, 5-norbornene-2,3-dicarboxyimido-yl-n-butylsulfonate, and n-trifluoromethylsulfonyloxynaphthylimide.

Examples of the oxime sulfonate derivatives are α-(benzenesulfoniumoxyimino)-4-methylphenylacetonitrile and α-(p-tolylsulfoniumoxyimino)-p-methoxyphenylacetonitrile.

Examples of the iminosulfonate derivatives include (5-(4-methylphenyl) sulfonyloxyimino-5H-thiophen-2-ylidene)-(2-methylphenyl) acetonitrile and (5-(4-(4-methylphenylsulfonyloxy)phenylsulfonyloxyimino)-5H-thiophen-2-ylidene)-(2-methylphenyl)-acetonitrile.

Also useful is 2-methyl-2-[(4-methylphenyl) sulfonyl]-1-[(4-methylthio)phenyl]-1-propane.

In the photosensitive resin composition, component (C) is preferably used in an amount of 0.05 to 20 parts by weight, more preferably 0.5 to 5 parts by weight per 100 parts by weight of component (A) from the viewpoint of photocurability. An amount of component (C) of at least 0.05 part by weight is preferable in that a sufficient amount of acid generates for crosslinking reaction to run to a full extent. An amount of component (C) of up to 20 parts by weight is effective for restraining the PAG from increasing its own absorptivity and eliminating the risk that the problem of transparency decline arises. Component (C) may be used alone or in admixture of two or more.

### [(D) Solvent]

The photosensitive resin composition may further contain (D) a solvent. The solvent used herein is not particularly limited as long as components (A) to (C) and foregoing various additives can be dissolved therein. Organic solvents are preferred because the components are effectively dissolved.

Illustrative examples of the organic solvent include ketones such as cyclohexanone, cyclopentanone and methyl-2-n-pentyl ketone; alcohols such as 3-methoxybutanol, 3-methyl-3-methoxybutanol, 1-methoxy-2-propanol, and 1-ethoxy-2-propanol; ethers such as propylene glycol monomethyl ether (PGME), ethylene glycol monomethyl ether, propylene glycol monoethyl ether, ethylene glycol monoethyl ether, propylene glycol dimethyl ether, and diethylene glycol dimethyl ether; and esters such as propylene glycol monomethyl ether acetate (PGMEA), propylene glycol monoethyl ether acetate, ethyl lactate, ethyl pyruvate, butyl acetate, methyl 3-methoxypropionate, ethyl 3-ethoxypropionate, tert-butyl acetate, tert-butyl propionate, and propylene glycol mono-tert-butyl ether acetate, and γ-butyrolactone. Of these solvents, ethyl lactate, cyclohexanone, cyclopentanone, PGMEA, γ-butyrolactone, and mixtures thereof are especially preferred because the PAG is most soluble.

In the photosensitive resin composition, it is preferred from the standpoints of compatibility and viscosity of the photosensitive resin composition that component (D) be used in an amount of 50 to 2,000 parts, more preferably 50 to 1,000 parts, and even more preferably 50 to 100 parts by weight per 100 parts by weight of component (A). Component (D) may be used alone or in admixture.

### [Other Additives]

Besides the aforementioned components, the photosensitive resin composition may contain other additives. One exemplary other additive is a surfactant which is commonly used for improving coating properties.

Preferred surfactants are nonionic surfactants, for example, fluorochemical surfactants such as perfluoroalkyl polyoxyethylene ethanols, fluorinated alkyl esters, perfluoroalkylamine oxides, and fluorinated organosiloxane compounds. These surfactants are commercially available. Illustrative examples include Fluorad® FC-430 from 3M, Surflon® S-141 and S-145 from AGC Seimi Chemical Co., Ltd., Unidyne® DS-401, DS-4031, and DS-451 from Daikin Industries Ltd., Megaface® F-8151 from DIC Corp., and X-70-093 from Shin-Etsu Chemical Co., Ltd. Preferred surfactants are Fluorad FC-430 and X-70-093. When the photosensitive resin composition contains the surfactant, the amount thereof is preferably 0.05 to 1 part by weight per 100 parts by weight of component (A).

The photosensitive resin composition may contain a silane coupling agent as the other additive. Inclusion of a silane coupling agent is effective for enhancing the adhesion of a coating of the composition to adherends. Suitable silane coupling agents include epoxy-containing silane coupling agents and aromatic group-containing aminosilane coupling agents. The silane coupling agent may be used alone or in admixture. When the photosensitive resin composition contains the silane coupling agent, the amount thereof is not particularly limited, and is preferably 0.01 to 5% by weight of the photosensitive resin composition.

The photosensitive resin composition is prepared by the standard method. For example, the photosensitive resin composition may be prepared by stirring and mixing the aforementioned components and if necessary, filtering off solids through a filter or the like.

The photosensitive resin composition as prepared above is advantageously used, for example, as a film-forming material for semiconductor device protective film, interconnection protective film, coverlay film, solder mask, and TSV dielectric film, and an adhesive between substrates in three-dimensional laminates.

### [Pattern Forming Process Using Photosensitive Resin Composition]

Another embodiment of the invention is a pattern forming process using the photosensitive resin composition, comprising the steps of:
(i) applying the photosensitive resin composition onto a substrate to form a photosensitive resin coating thereon,
(ii) exposing the photosensitive resin coating to radiation, and
(iii) developing the exposed resin coating in a developer to form a pattern of the resin coating.

In step (i), the photosensitive resin composition is applied onto a substrate to form a photosensitive resin coating thereon. Examples of the substrate include silicon wafers, TSV silicon wafers, silicon wafers which have been thinned by back side polishing, plastic substrates, ceramic substrates, and substrates having a metal coating of Ni or Au wholly or partly on the surface by ion sputtering or plating. Sometimes, rugged or stepped substrates are used.

A method of forming the photosensitive resin coating is, for example, by coating the photosensitive resin composition onto a substrate and, if necessary, prebaking the coating. The coating technique may be any well-known technique, for example, dipping, spin coating, roll coating or the like. The coating weight of the photosensitive resin composition may be selected as appropriate for a particular purpose, preferably so as to form a photosensitive resin coating having a thickness of 0.1 to 200 μm, more preferably 1 to 150 μm.

A pre-wetting technique of dispensing a solvent dropwise on a substrate prior to coating of the photosensitive resin composition may be employed for the purpose of making the coating thickness on the substrate surface more uniform. The type and amount of the solvent dispensed dropwise may be selected for a particular purpose. For example, alcohols such as isopropyl alcohol (IPA), ketones such as cyclohexanone, and glycols such as PGME are preferred. The solvent used in the photosensitive resin composition may also be used.

At this point, the coating may be prebaked to evaporate off the solvent and the like, if necessary, so that the coating is ready for efficient photo-cure reaction. Prebake may be performed, for example, at 40 to 140° C. for 1 minute to about 1 hour.

Next, in step (ii), the photosensitive resin coating is exposed to radiation. The exposure radiation is preferably of wavelength 10 to 600 nm, more preferably 190 to 500 nm. Examples of radiation in the wavelength range include radiation of various wavelengths from radiation-emitting units, specifically UV radiation such as g-line, h-line or i-line, and deep UV (248 nm, 193 nm). Among these, radiation of wavelength 248 to 436 nm is preferred. An appropriate exposure dose is 10 to 10,000 mJ/cm².

Exposure may be made through a photomask. The photomask may be, for example, one perforated with a desired pattern. Although the material of the photomask is not particularly limited, a material capable of shielding radiation in the above wavelength range. For example, a mask having a light-shielding film of chromium is preferred.

The next step may be post-exposure bake (PEB) which is effective for enhancing development sensitivity. PEB is preferably performed at 40 to 150° C. for 0.5 to 10 minutes. The exposed region of the resin coating is crosslinked by PEB to form an insolubilized pattern which is insoluble in an organic solvent as developer.

The exposure or PEB is followed by the step (iii) of developing the exposed resin coating in a developer to form a pattern of the resin coating. The preferred developers are organic solvents including alcohols such as IPA, ketones such as cyclohexanone, and glycols such as PGME. The solvent used in the photosensitive resin composition is also useful. Development is performed in a conventional manner, for example, by dipping the potentially patterned coating in the developer. The unexposed region of the resin coating is dissolved away by organic solvent development, forming a pattern. The development is followed by washing, rinsing and drying if necessary. In this way, a resin coating having the desired pattern is obtained.

In step (iv), the patterned coating may be post-cured in an oven or on a hot plate at a temperature of preferably 100 to 250° C., more preferably 130 to 220° C. A post-cure temperature of 100 to 250° C. is effective for increasing the crosslinking density of the photosensitive resin composition and removing any residual volatile matter, which is preferred from the standpoints of adhesion to substrates, heat resistance, mechanical strength, electric properties, and bond strength. The post-cure time is preferably 10 minutes to 10 hours, more preferably 10 minutes to 3 hours. The photosensitive resin composition ensures that a coating having improved film properties is obtained even after post-cure at a relatively low temperature of 200° C. or lower. The resin coating as post-cured (or cured coating) typically has a thickness of 1 to 200 μm, preferably 5 to 50 μm.

When it is unnecessary to form a pattern, for example, when it is simply desired to form a uniform film, the same pattern forming process as above may be followed except that in step (ii), the resin coating is exposed to radiation of suitable wavelength without the photomask.

### [Substrate Bonding Method]

The photosensitive resin composition of the invention may also be used as an adhesive for bonding two substrates. The substrate bonding method may be a method of joining a first substrate having a coating of the resin composition formed thereon to a second substrate under a sufficient set of temperature and pressure conditions to form an adhesive bond between the substrates. One or both of the first substrate having a resin coating and the second substrate may have been cut into a chip such as by dicing. The preferred bonding conditions include a temperature of 50 to 200° C. and a time of 1 to 60 minutes. Any desired bonding units may be used, for example, a wafer bonder for bonding wafers under reduced pressure and under a certain load, or a flip chip bonder for performing chip-wafer or chip-chip bonding. The adhesive layer between substrates may be subjected to post-cure treatment into a permanent bond having augmented bond strength.

The thus joined or bonded substrates may be post-cured under the same conditions as in the above step (iv), for thereby increasing the crosslinking density of the resin coating to enhance substrate bonding force. It is noted that crosslinking reaction occurs by the heat during bonding. Since this crosslinking reaction is not accompanied with side reaction entailing degassing, no bonding voids are induced when the photosensitive resin composition is used as the substrate adhesive.

### [Photosensitive Dry Film]

A further embodiment of the invention is a photosensitive dry film comprising a support and the photosensitive resin coating of the photosensitive resin composition thereon.

The photosensitive dry film (support+photosensitive resin coating) is solid, and the photosensitive resin coating contains no solvent. This eliminates the risk that bubbles resulting from volatilization of solvent are left within the resin coating and between the resin coating and the rugged or stepped substrate.

The photosensitive resin coating has a thickness of preferably 5 to 200 μm, more preferably 10 to 100 μm when planarity and step coverage on a rugged or stepped substrate and a substrate lamination spacing are taken into account.

Furthermore, the viscosity and fluidity of the photosensitive resin coating are closely correlated. As long as the photosensitive resin coating has a proper range of viscosity, it exhibits a sufficient fluidity to fill deeply even in a narrow gap or it softens to enhance the adhesion to the substrate. Accordingly, from the standpoint of fluidity, the photosensitive resin coating should preferably have a viscosity in the range of 10 to 5,000 Pa·s, more preferably 30 to 2,000 Pa·s, and even more preferably 50 to 300 Pa·s at a temperature of 80 to 120° C. It is noted that the viscosity is measured by a rotational viscometer.

The photosensitive dry film has the advantage that when tightly attached to a substrate having asperities on its surface, the photosensitive resin coating is coated so as to conform to the asperities, achieving a high flatness. Since the photosensitive resin coating is characterized by a low viscoelasticity, a higher flatness is achievable. Further, if the photosensitive resin coating is in close contact with the substrate in a vacuum environment, generation of gaps therebetween is effectively inhibited.

The photosensitive dry film may be manufactured by coating the photosensitive resin composition to a support and drying the resin composition into a resin coating. An apparatus for manufacturing the photosensitive dry film may be a film coater commonly used in the manufacture of pressure-sensitive adhesive products. Suitable film coaters include, for example, a comma coater, comma reverse coater, multiple coater, die coater, lip coater, lip reverse coater, direct gravure coater, offset gravure coater, three-roll bottom reverse coater, and four-roll bottom reverse coater.

The support (film) is unwound from a supply roll in the film coater, passed across the head of the film coater where the photosensitive resin composition is coated onto the support to the predetermined buildup, and then moved through a hot air circulating oven at a predetermined temperature for a predetermined time, where the photosensitive resin coating is dried on the support, obtaining a photosensitive dry film. If necessary, the photosensitive dry film and a protective film which is unwound from another supply roll in the film coater are passed across a laminate roll under a predetermined pressure whereby the protective film is bonded to the photosensitive resin coating on the support, whereupon the laminate is wound up on a take-up shaft in the film coater, obtaining a protective film-bearing photosensitive dry film. Preferably, the oven temperature is 25 to 150° C., the pass time is 1 to 100 minutes, and the bonding pressure is 0.01 to 5 MPa.

The support film used herein may be a single film or a multilayer film consisting of a plurality of stacked layers. Examples of the film material include synthetic resins such as polyethylene, polypropylene, polycarbonate and polyethylene terephthalate (PET), with the PET film being preferred for appropriate flexibility, mechanical strength and heat resistance. These films may have been pretreated such as by corona treatment or coating of a release agent. Such films are commercially available, for example, Cerapeel® WZ(RX) and Cerapeel® BX8(R) from Toray Advanced Film Co., Ltd.; E7302 and E7304 from Toyobo Co., Ltd.; Purex® G31 and Purex® G71T1 from Teijin DuPont Films Japan Ltd.; and PET38×1-A3, PET38×1-V8 and PET38×1-X08 from Nippa Co., Ltd.

The protective film used herein may be similar to the support film. Among others, PET and polyethylene films having an appropriate flexibility are preferred. Such films are also commercially available. For example, PET films are as mentioned above, and polyethylene films include GF-8 from Tamapoly Co., Ltd. and PE film 0 type from Nippa Co., Ltd.

Both the support and protective films preferably have a thickness of 10 to 100 μm, more preferably 25 to 50 μm, for consistent manufacture of photosensitive dry film, and prevention of wrapping or curling on a take-up roll.

### [Pattern Forming Process Using Photosensitive Dry Film]

A further embodiment of the invention is a pattern forming process using the photosensitive dry film, comprising the steps of:
(i′) using the photosensitive dry film to form the photosensitive resin coating on a substrate,
(ii) exposing the photosensitive resin coating to radiation,
(iii) developing the exposed resin coating in a developer to form a pattern of the resin coating.

In step (i′), the photosensitive dry film is used to form the photosensitive resin coating on a substrate. Specifically, the photosensitive dry film at its photosensitive resin coating is attached to a substrate to form the photosensitive resin coating on the substrate. When the photosensitive dry film is covered with the protective film, the dry film at its photosensitive resin coating is attached to a substrate after stripping the protective film therefrom, to form the photosensitive resin coating on the substrate. The dry film may be attached using a film attachment apparatus.

Examples of the substrate include the same substrates as exemplified above in the pattern forming process using the photosensitive resin composition. The film attachment apparatus is preferably a vacuum laminator. The protective film is stripped from the photosensitive dry film. In the vacuum chamber kept at a predetermined vacuum, the bare photosensitive resin coating of the dry film is closely bonded to the substrate on a table at a predetermined temperature, using a bonding roll under a predetermined pressure. Preferably, the temperature is 60 to 120° C., the pressure is 0 to 5.0 MPa, and the vacuum is 50 to 500 Pa.

The attachment of dry film may be repeated plural times, if necessary to obtain a photosensitive resin coating having the desired thickness. The attachment step is repeated 1 to 10 times, for example, before a photosensitive resin coating having a thickness of the order of about 10 to 1,000 μm, preferably about 100 to 500 μm is obtained.

The assembly of the photosensitive resin coating on the substrate may be prebaked, if necessary, for facilitating photo-cure reaction of the photosensitive resin coating or enhancing the adhesion between the resin coating and the substrate. Prebake may be performed, for example, at 40 to 140° C. for 1 minute to about 1 hour.

Like the pattern forming process using the photosensitive resin composition, the photosensitive resin coating attached to the substrate may be subjected to steps of (ii) exposing the photosensitive resin coating to radiation, (iii) developing the exposed resin coating in a developer to form a pattern of the resin coating, and optionally (iv) post-curing the patterned coating. It is noted that the support of the photosensitive dry film may be removed before prebake or before PEB, by mechanical stripping or the like, depending on a particular process.

The resin coating obtained from the photosensitive resin composition or photosensitive dry film has excellent solder resistance, heat resistance, low substrate warpage, mechanical properties such as crack resistance, copper migration resistance, and adhesion to substrates or the like, and can be used as a protective film for electric and electronic parts and a film for bonding substrates.

### EXAMPLES

Synthesis Examples, Examples and Comparative Examples are given below for illustrating the invention although the invention is not limited thereto. Notably, the Mw is measured by GPC versus monodisperse polystyrene standards using GPC column TSKgel Super HZM-H (Tosoh Corp.) under analytical conditions: flow rate 0.6 mL/min, THF elute, and column temperature 40° C.

Compounds used for the synthesis of polymers are shown below.

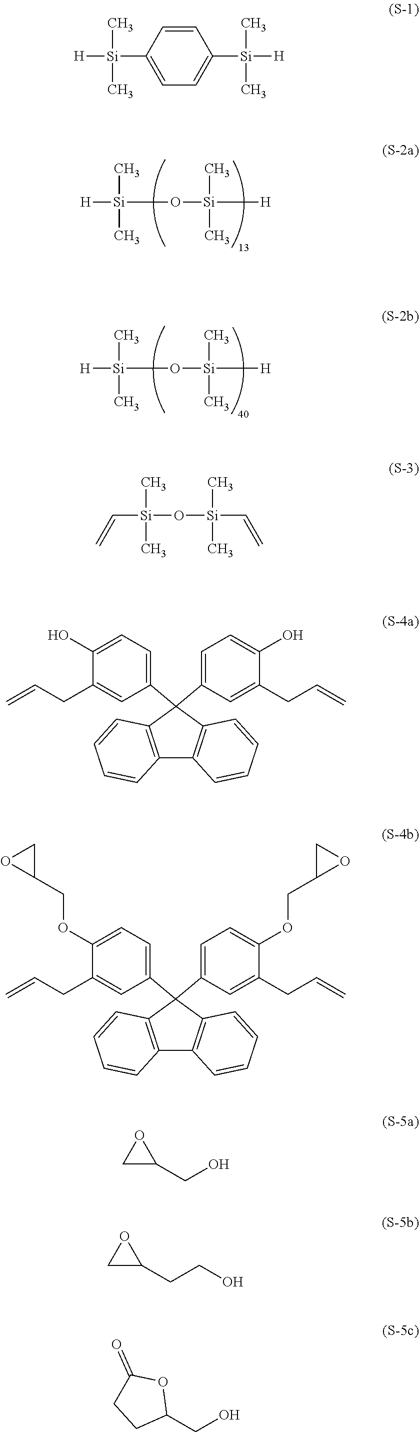

### [Synthesis Example 1] Synthesis of Polymer P-1

To a 10 L flask equipped with a stirrer, a thermometer, a nitrogen replacement device, and a reflux condenser were added 245.4 g (0.235 mol) of a compound having formula (S-2a) and 430.5 g (1.00 mol) of a compound having formula (S-4a), then 1,500 g of toluene was added to the flask, and the resulting mixture was heated to 70° C. Then, 1.0 g of a toluene solution of a chloroplatinic acid (platinum concentration: 0.5 wt %) was charged to the flask, and 142.9 g (0.735 mol) of a compound having formula (S-1) was added dropwise thereto over 1 hour (total of hydrosilyl groups: total of alkenyl groups=0.97:1 (molar ratio)). After completion of the dropwise addition, the resulting mixture was heated to 90° C. and aged for 11 hours, and then toluene was distilled off from the reaction solution under reduced pressure to give a polymer. To the polymer, 2,000 g of propylene glycol monomethyl ether was added, and after the dissolution of propylene glycol monomethyl ether was confirmed, 444.5 g (6.00 mol) of a compound having formula (S-5a) and 10.1 g (0.10 mol) of triethylamine were added thereto, and the resulting mixture was heated at 80° C. for 12 hours. After completion of the reaction, propylene glycol monomethyl ether and triethylamine were distilled off from the reaction solution under reduced pressure to give Polymer P-1. Polymer P-1 had a Mw of 8,000. The Mw was measured in terms of polystyrene by gel permeation chromatography (GPC) using tetrahydrofuran as an elution solvent. Polymer P-1 was confirmed to be a polymer containing the repeat unit having formula (A1) and the repeat unit having formula (A2) by ¹H-NMR (manufactured by Bruker Corporation).

### [Synthesis Example 2] Synthesis of Polymer P-2

To a 10 L flask equipped with a stirrer, a thermometer, a nitrogen replacement device, and a reflux condenser were added 530.5 g (0.18 mol) of a compound having formula (S-2b), 387.5 g (0.90 mol) of the compound having formula (S-4a), and 18.64 g (0.10 mol) of a compound having formula (S-3), then 1,500 g of toluene was added to the flask, and the resulting mixture was heated to 70° C. Then, 1.0 g of a toluene solution of a chloroplatinic acid (platinum concentration: 0.5 wt %) was charged to the flask, and 153.6 g (0.79 mol) of the compound having formula (S-1) was added dropwise thereto over 1 hour (total of hydrosilyl groups: total of alkenyl groups=0.97:1 (molar ratio)). After completion of the dropwise addition, the resulting mixture was heated to 90° C. and aged for 11 hours, and then toluene was distilled off from the reaction solution under reduced pressure to give a polymer. To the polymer, 2,000 g of propylene glycol monomethyl ether was added, and after the dissolution of propylene glycol monomethyl ether was confirmed, 400.0 g (5.40 mol) of the compound having formula (S-5a) and 9.11 g (0.09 mol) of triethylamine were added thereto, and the resulting mixture was heated at 80° C. for 12 hours. After completion of the reaction, propylene glycol monomethyl ether and triethylamine were distilled off from the reaction solution under reduced pressure to give Polymer P-2. Polymer P-2 had a Mw of 80,000. Polymer P-2 was confirmed to be a polymer containing the repeat unit having formula (A1), the repeat unit having formula (A2), the repeat unit having formula (A3), and the repeat unit having formula (A4) by ¹H-NMR (manufactured by Bruker Corporation).

### [Synthesis Example 3] Synthesis of Polymer P-3

To a 10 L flask equipped with a stirrer, a thermometer, a nitrogen replacement device, and a reflux condenser were added 245.4 g (0.235 mol) of the compound having formula (S-2a) and 430.5 g (1.00 mol) of the compound having formula (S-4a), then 1,500 g of toluene was added to the flask, and the resulting mixture was heated to 70° C. Then, 1.0 g of a toluene solution of a chloroplatinic acid (platinum concentration: 0.5 wt %) was charged to the flask, and 142.9 g (0.735 mol) of the compound having formula (S-1) was added dropwise thereto over 1 hour (total of hydrosilyl groups: total of alkenyl groups=0.97:1 (molar ratio)). After completion of the dropwise addition, the resulting mixture was heated to 90° C. and aged for 11 hours, and then toluene was distilled off from the reaction solution under reduced pressure to give a polymer. To the polymer, 2,000 g of propylene glycol monomethyl ether was added, and after the dissolution of propylene glycol monomethyl ether was confirmed, 528.6 g (6.00 mol) of a compound having formula (S-5b) and 10.1 g (0.10 mol) of triethylamine were added thereto, and the resulting mixture was heated at 80° C. for 12 hours. After completion of the reaction, propylene glycol monomethyl ether and triethylamine were distilled off from the reaction solution under reduced pressure to give Polymer P-3. Polymer P-3 had a Mw of 8,500. Polymer P-3 was confirmed to be a polymer containing the repeat unit having formula (A1) and the repeat unit having formula (A2) by ¹H-NMR (manufactured by Bruker Corporation).

### [Synthesis Example 4] Synthesis of Polymer P-4

To a 10 L flask equipped with a stirrer, a thermometer, a nitrogen replacement device, and a reflux condenser were added 245.4 g (0.235 mol) of the compound having formula (S-2a) and 430.5 g (1.00 mol) of the compound having formula (S-4a), then 1,500 g of toluene was added to the flask, and the resulting mixture was heated to 70° C. Then, 1.0 g of a toluene solution of a chloroplatinic acid (platinum concentration: 0.5 wt %) was charged to the flask, and 142.9 g (0.735 mol) of the compound having formula (S-1) was added dropwise thereto over 1 hour (total of hydrosilyl groups: total of alkenyl groups=0.97:1 (molar ratio)). After completion of the dropwise addition, the resulting mixture was heated to 90° C. and aged for 11 hours, and then toluene was distilled off from the reaction solution under reduced pressure to give a polymer. To the polymer, 2,000 g of propylene glycol monomethyl ether was added, and after the dissolution of propylene glycol monomethyl ether was confirmed, 696.7 g (6.00 mol) of a compound having formula (S-5c) and 10.1 g (0.10 mol) of triethylamine were added thereto, and the resulting mixture was heated at 80° C. for 12 hours. After completion of the reaction, propylene glycol monomethyl ether and triethylamine were distilled off from the reaction solution under reduced pressure to give Polymer P-4. Polymer P-4 had a Mw of 9,000. Polymer P-4 was confirmed to be a polymer containing the repeat unit having formula (A1) and the repeat unit having formula (A2) by ¹H-NMR (manufactured by Bruker Corporation).

### [Comparative Synthesis Example 1] Synthesis of Comparative Polymer CP-1

To a 10 L flask equipped with a stirrer, a thermometer, a nitrogen replacement device, and a reflux condenser were added 401 g (0.50 mol) of the compound having formula (S-2a), 488 g (0.90 mol) of a compound having formula (S-4b), and 18.6 g (0.10 mol) of the compound having formula (S-3), then 1,100 g of toluene was added to the flask, and the resulting mixture was heated to 80° C. Then, 1.0 g of a toluene solution of a chloroplatinic acid (platinum concentration: 0.5 wt %) was charged to the flask, and 95.3 g (0.49 mol) of the compound having formula (S-1) was added dropwise thereto over 1 hour (total of hydrosilyl groups: total of alkenyl groups=0.99:1 (molar ratio)). After completion of the dropwise addition, the resulting mixture was heated to 100° C. and aged for 6 hours, and then toluene was distilled off from the reaction solution under reduced pressure to give Comparative Polymer CP-1. Comparative Polymer CP-1 had a Mw of 12,000.

### [Comparative Synthesis Example 2] Synthesis of Comparative Polymer CP-2

To a 10 L flask equipped with a stirrer, a thermometer, a nitrogen replacement device, and a reflux condenser were added 362 g (0.45 mol) of the compound having formula (S-2b), 215 g (0.50 mol) of the compound having formula (S-4a), and 271 g (0.50 mol) of the compound having formula (S-4b), then 2,100 g of toluene was added to the flask, and the resulting mixture was heated to 70° C. Then, 2.0 g of a toluene solution of a chloroplatinic acid (platinum concentration: 0.5 wt %) was charged to the flask, and 105 g (0.54 mol) of the compound having formula (S-1) was added dropwise thereto over 1 hour (total of hydrosilyl groups: total of alkenyl groups=0.99:1 (molar ratio)). After completion of the dropwise addition, the resulting mixture was heated to 100° C. and aged for 12 hours, and then toluene was distilled off from the reaction solution under reduced pressure to give Comparative Polymer CP-2. Comparative Polymer CP-2 had a Mw of 14,000.

### [2] Preparation of Photosensitive Resin Composition

### Examples 1 to 8 and Comparative Examples 1 to 10

Photosensitive resin compositions of Examples 1 to 8 and Comparative Examples 1 to 10 were prepared by blending the components in the amounts shown in Tables 1 to 2, agitating them at room temperature until dissolution, and precision filtering through a Teflon® filter with a pore size of 1.0 μm.

TABLE 1

| | | | Example | | | | | | | |
|---|---|---|---|---|---|---|---|---|---|---|
| Component | | | 1 | 2 | 3 | 4 | 5 | 6 | 7 | 8 |
| (A) | Polymer | P-1 | 100 | — | — | — | 100 | — | — | — |
| | | P-2 | — | 100 | — | — | — | 100 | — | — |
| | | P-3 | — | — | 100 | — | — | — | 100 | — |
| | | P-4 | — | — | — | 100 | — | — | — | — |
| | | CP-1 | — | — | — | — | — | — | — | — |
| | | CP-2 | — | — | — | — | — | — | — | — |
| | | CP-3 | — | — | — | — | — | — | — | — |
| (B) | Crosslinker | B-1 | 3 | 25 | — | — | — | — | — | — |
| | | B-2 | — | — | 3 | 25 | — | — | — | — |
| | | B-3 | — | — | — | — | 3 | 25 | — | — |
| | | B-4 | — | — | — | — | v | — | 3 | 25 |
| | | B′-1 | — | — | — | — | | — | — | — |
| | | B′-2 | — | — | — | — | | — | — | — |
| | | B′-3 | — | — | — | — | | — | — | — |
| (C) | Photoacid | C-1 | 0.5 | 1 | 3 | 5 | | — | — | — |
| | generator | C-2 | — | — | — | — | 0.5 | 1 | 3 | 5 |
| (D) | Solvent | PGMEA | 55 | 55 | 55 | 55 | 55 | 55 | 55 | 55 |

TABLE 2

| | | | Comparative Example | | | | | | | | | |
|---|---|---|---|---|---|---|---|---|---|---|---|---|
| Component | | | 1 | 2 | 3 | 4 | 5 | 6 | 7 | 8 | 9 | 10 |
| (A) | Polymer | P-1 | 100 | — | 100 | — | — | — | — | — | — | — |
| | | P-2 | | 100 | — | 100 | — | — | — | — | — | — |
| | | P-3 | — | — | — | — | 100 | — | — | — | — | — |
| | | P-4 | — | — | — | — | — | 100 | — | — | — | — |
| | | CP-1 | — | — | — | — | — | — | 100 | — | — | — |
| | | CP-2 | — | — | — | — | — | — | — | 100 | — | 100 |
| | | CP-3 | — | — | — | — | — | — | — | — | 100 | — |
| (B) | Crosslinker | B-1 | — | — | — | — | — | — | 25 | — | — | — |
| | | B-2 | — | — | — | — | — | — | — | 25 | — | — |
| | | B-3 | — | — | — | — | — | — | — | — | 25 | — |
| | | B-4 | — | — | — | — | — | — | — | — | — | 25 |
| | | B′-1 | — | — | 25 | — | — | — | — | — | — | — |
| | | B′-2 | — | — | — | 25 | — | — | — | — | — | — |
| | | B′-3 | — | — | — | — | — | 25 | — | — | — | — |
| (C) | Photoacid generator | C-1 | 0.5 | 1 | — | — | — | — | 0.5 | 1 | 3 | 5 |
| | | C-2 | — | — | 0.5 | 1 | 3 | 5 | — | — | — | — |
| (D) | Solvent | PGMEA | 55 | 55 | 55 | 55 | 55 | 55 | 55 | 55 | 55 | 55 |

In Tables 1 and 2, crosslinkers B-1 to B-4 and B′-1 to B′-2 are identified below. B-3 is 2,2′,6,6′-tetramethoxymethyl bisphenol A, and B′-3 is DURANATE TMA-100 (manufactured by Asahi Kasei Corp.) as an isocyanate crosslinker.

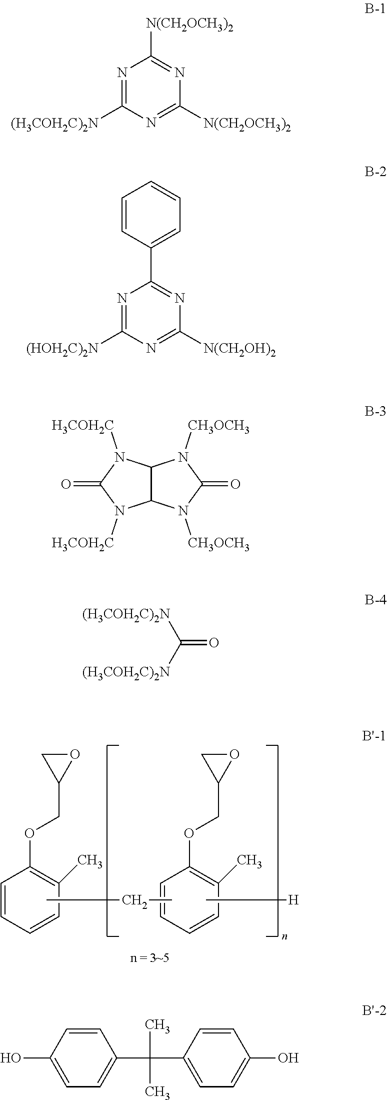

In Tables 1 and 2, photoacid generators C-1 and C-2 are identified below.

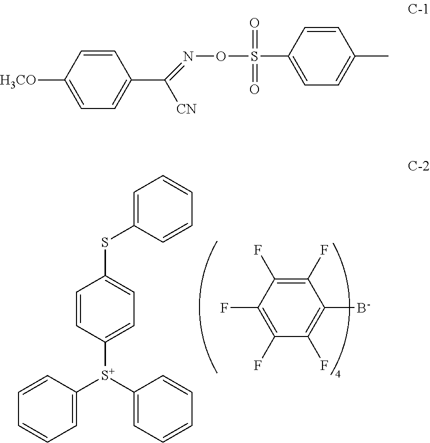

In Tables 1 and 2, Comparative Polymer CP-3 is identified below.

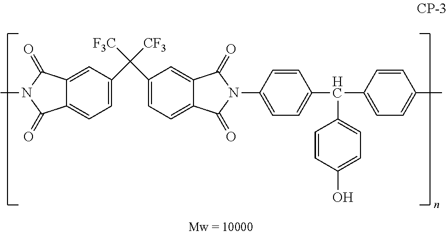

### [3] Preparation of Photosensitive Dry Film

A die coater was used as the film coater and a polyethylene terephthalate (PET) film of 38 μm thick was used as the support film. Each of the photosensitive resin compositions in Tables 1 to 3 was coated onto the support film. The coated film was passed through a hot air circulating oven (length 4 m) set at 100° C. over 5 minutes to form a photosensitive resin coating on the support film, yielding a photosensitive dry film. Using a laminating roll, a polyethylene film of 50 μm thick as the protective film was bonded to the photosensitive resin coating under a pressure of 1 MPa, yielding a protective film-bearing photosensitive dry film. Each photosensitive resin coating had a thickness of 50 μm. The thickness of a photosensitive resin coating was measured by an optical interference film thickness instrument F50-EXR (Filmetrics, Inc.).

### [4] Evaluation of Resin Coating

### (1) Pattern Formation and Evaluation

From the protective film-bearing photosensitive dry film, the protective film was stripped off. Using a vacuum laminator TEAM-100RF (Takatori Corp.) with a vacuum chamber set at a vacuum of 80 Pa, the photosensitive resin coating on the support film was closely bonded to a migration test substrate (comb-shaped electrode-bearing substrate, conductor: copper, conductor spacing and width: 10 μm, conductor thickness: 4 μm). The temperature was 100° C. After restoration of atmospheric pressure, the substrate was taken out of the laminator, and the support film was stripped off. Then the photosensitive resin coating was prebaked on a hot plate at 120° C. for 5 minutes for enhancing its adhesion to the substrate. Next, using a contact aligner exposure tool, the photosensitive resin coating was exposed to radiation of wavelength 365 nm through a mask having a line-and-space pattern and a contact hole pattern. After exposure, the coated substrate was baked (PEB) on a hot plate at 140° C. for 5 minutes and cooled. This was followed by spray development in PGMEA for 300 seconds for forming a pattern of the resin coating.

The patterned photosensitive resin coating on the substrate was post-cured in an oven at 190° C. for 2 hours while the oven was purged with nitrogen. Under a scanning electron microscope (SEM), the contact hole patterns of 100 μm, 50 μm, and 30 μm were observed in cross section, with the minimum hole pattern in which holes extended down to the film bottom being reported as maximum resolution. From the cross-sectional photo, the contact hole pattern of 100 μm was evaluated for perpendicularity, and rated “excellent (⊚)” for perpendicular pattern, “good (◯)” for slight inversely tapered profile or footing, “fair (Δ)” for noticeable inversely tapered profile or footing, and “poor (x)” for opening failure. The results are shown in Tables 3 to 4.

### (2) Evaluation of Electrical Characteristics (Copper Migration)

The substrate on which the pattern was formed using the method (1) was used as a substrate for copper migration evaluation to perform a test. The copper migration test was performed under conditions of a temperature of 121° C., a humidity of 100%, and an applied voltage of 10 V to check the time at which short-circuit occurred with the upper limit of 1,000 hours. A case where there was no short-circuit was rated “good (O)”. The results are shown in Tables 3 to 4.

### (3) Evaluation of Reliability (Adhesion and Crack Resistance)

From the protective film-bearing photosensitive dry film, the protective film was stripped off. Using a vacuum laminator TEAM-100RF (Takatori Corp.) with a vacuum chamber set at a vacuum of 80 Pa, the photosensitive resin coating on the support film was closely bonded to a CCL substrate having a silicon chip of 10 mm by 10 mm squares disposed thereon. The temperature was 100° C. After restoration of atmospheric pressure, the substrate was taken out of the laminator, and the support film was stripped off. Then the photosensitive resin coating was prebaked on a hot plate at 120° C. for 5 minutes for enhancing its adhesion to the substrate. Using a contact aligner exposure tool, the photosensitive resin coating was then exposed to radiation of wavelength 365 nm without any interposing mask. After the exposure, the photosensitive resin coating was baked (PEB) on a hot plate at 140° C. for 5 minutes, cooled, and post-cured in an oven at 190° C. for 2 hours while the oven was purged with nitrogen. Thereafter, using a dicing saw with a dicing blade (DAD685 by DISCO Co., spindle revolution 40,000 rpm, cutting rate 20 mm/sec), the substrate was cut into specimens of 20 mm by 20 mm squares so that the circumference of the silicon chip was 5 mm. Ten specimens for each Example were examined by a thermal cycling test (test of holding at −55° C. for 10 minutes and holding at 125° C. for 10 minutes, the test being repeated 1,000 cycles). After the thermal cycling test, it was observed whether or not the resin film peeled from the wafer and whether or not the resin film cracked. The sample was rated “good (◯)” when all specimens did not peel or crack, “peeled (x)” when one or more specimens peeled, and “cracked (x)” when one or more specimens cracked. The means for determining whether or not a specimen peeled or cracked were top-down observation under an optical microscope and cross-sectional observation under SEM. The results are shown in Tables 3 to 4.

### (4) Evaluation of Adhesion Strength (Before Heat Resistance Test)

From the protective film-bearing photosensitive dry film, the protective film was stripped off. Using a vacuum laminator TEAM-100RF (Takatori Corp.) with a vacuum chamber set at a vacuum of 80 Pa, the photosensitive resin coating on the support film was closely bonded to a silicon wafer of 8 inch. The temperature was 100° C. After restoration of atmospheric pressure, the substrate was taken out of the laminator, and the support film was stripped off. Then the photosensitive resin coating was preheated on a hot plate at 120° C. for 5 minutes. Then, using a contact aligner exposure tool, the photosensitive resin coating was then exposed to radiation of wavelength 365 nm without any interposing mask. Using a dicing saw with a dicing blade (DAD685 by DISCO Co.), the substrate was cut into a chip of 2 mm by 2 mm squares. The chip of 2 mm by 2 mm squares was attached to a separately furnished silicon wafer of 15 mm by 15 mm squares (i.e., base substrate) through the resin film at 150° C. and load 50 mN. The resin film was then cured by heating at 190° C. for 2 hours, obtaining a test piece. Five test pieces for each Example were subjected to an adhesion strength measuring test. Using a bond tester Dage series 4000-PXY (DAGE), the resisting force exerted when the semiconductor chip (2 mm by 2 mm) was peeled from the base substrate (silicon wafer of 15 mm by 15 mm squares) was measured for evaluating the adhesion strength of the resin film layer. The test conditions included test speed 200 μm/sec and test height 50 μm. The results are shown in Tables 3 to 4. The value is an average of measurements of 5 test pieces, with a larger value indicating higher adhesion strength.

(5) Evaluation of Adhesion Strength (after Heat Resistance Test)

After the test piece for adhesion strength measurement prepared in (4) was allowed to stand in an oven at 240° C. for 100 hours, it was taken out of the oven and subjected to the adhesion strength measuring test as in (5). The results are shown in Tables 3 to 4.

### (6) Evaluation of Photoresist Stripper Resistance

In order to evaluate solvent resistance to a N-methyl-2-pyrrolidone (NMP) solution containing 30% of tetramethylammonium hydroxide (TMAH), which is a photoresist stripper having a relatively high dissolving power, using each of the photosensitive resin compositions of Examples 1 to 8 and Comparative Examples 1 to 10, a 15 mm×15 mm pattern was formed on a silicon wafer using the same method as that of the preparation of the wafer for the copper migration test of (1). After dipping the wafer in the N-methyl-2-pyrrolidone (NMP) solution containing 30% of tetramethylammonium hydroxide (TMAH) at 40° C. for 1 hour, a change in thickness and external appearance were inspected to evaluate the photoresist stripper resistance. A case where there was no change in the external appearance and the thickness was evaluated as “O”, and a case where swelling or the like was observed was evaluated as “x”. The results are shown in Tables 3 to 4.

TABLE 3

| | | Example | | | | | | | |
|---|---|---|---|---|---|---|---|---|---|
| | | 1 | 2 | 3 | 4 | 5 | 6 | 7 | 8 |
| Pattern | Maximum resolution (μm) | 30 | 30 | 30 | 30 | 30 | 30 | 30 | 30 |
| formation | Pattern shape | ⊚ | ⊚ | ⊚ | ⊚ | ⊚ | ⊚ | ⊚ | ⊚ |
| Copper migration test 1,000 hr | | ◯ | ◯ | ◯ | ◯ | ◯ | ◯ | ◯ | ◯ |
| (short-circuit duration hr) | | | | | | | | | |
| Reliability | Adhesion | ◯ | ◯ | ◯ | ◯ | ◯ | ◯ | ◯ | ◯ |
| | Crack resistance | ◯ | ◯ | ◯ | ◯ | ◯ | ◯ | ◯ | ◯ |
| Adhesion | Initial | 16 | 17 | 15 | 16 | 16 | 17 | 15 | 16 |
| strength | After heat resistance test | 16 | 17 | 15 | 16 | 16 | 17 | 15 | 16 |
| (MPa) | | | | | | | | | |

| | | | | | | | | |
|---|---|---|---|---|---|---|---|---|
| Photoresist stripper resistance | ◯ | ◯ | ◯ | ◯ | ◯ | ◯ | ◯ | ◯ |

TABLE 4

| | | Comparative Example | | | | | | | | | |
|---|---|---|---|---|---|---|---|---|---|---|---|
| | | 1 | 2 | 3 | 4 | 5 | 6 | 7 | 8 | 9 | 10 |
| Pattern | Maximum resolution (μm) | X | X | 100 | X | X | X | 100 | 100 | 100 | 100 |
| formation | Pattern shape | X | X | Δ | X | X | X | Δ | Δ | Δ | Δ |
| Copper migration test 1,000 hr | | 100 | 100 | 500 | 100 | 300 | 300 | 600 | 500 | 600 | 600 |
| (short-circuit duration hr) | | | | | | | | | | | |
| Reliability | Adhesion | X | X | X | X | X | X | X | X | X | X |
| | Crack resistance | X | X | X | X | X | X | X | X | X | X |
| Adhesion strength | Initial | 3 | 3 | 12 | 3 | 9 | 9 | 11 | 12 | 11 | 12 |
| (MPa) | After heat resistance test | 2 | 2 | 10 | 2 | 7 | 7 | 8 | 9 | 9 | 10 |

| | | | | | | | | | | |
|---|---|---|---|---|---|---|---|---|---|---|
| Photoresist stripper resistance | X | X | X | X | X | X | X | X | X | X |

As is evident from the test results, the photosensitive resin compositions and photosensitive dry films within the scope of the invention are easy to form perpendicular small-size patterns in thick film form and exhibit satisfactory properties as photosensitive material. The cured coatings obtained therefrom have excellent copper migration resistance, photoresist stripper resistance, adhesion to substrates or the like, and heat resistance, have high reliability as insulating protective film in terms of crack resistance and adhesion, and are thus useful materials for forming protective films on electric and electronic parts including circuit substrates, semiconductor devices and display devices. Therefore, photosensitive resin compositions and photosensitive dry films having higher reliability are provided according to the invention.

Japanese Patent Application No. 2024-047468 is incorporated herein by reference. Although some preferred embodiments have been described, many modifications and variations may be made thereto in light of the above teachings. It is therefore to be understood that the invention may be practiced otherwise than as specifically described without departing from the scope of the appended claims.

1. A photosensitive resin composition comprising:
(A) a polymer having a silphenylene skeleton, a polysiloxane skeleton, and a fluorene skeleton in a main chain, and containing a polyhydric alcohol structure in a side chain;
(B) at least one crosslinker selected from among a nitrogen-containing compound selected from melamine, guanamine, glycoluril, and urea compounds, having on the average at least two methylol and/or alkoxymethyl groups per molecule, an amino condensate modified with formaldehyde or formaldehyde-alcohol, and a phenol compound having on the average at least two methylol or alkoxymethyl groups per molecule; and
(C) a photoacid generator.

2. The photosensitive resin composition according to claim 1, wherein polymer (A) includes a repeat unit having formula (A1) and a repeat unit having formula (A2), and may further include a repeat unit having formula (A3) and a repeat unit having formula (A4): 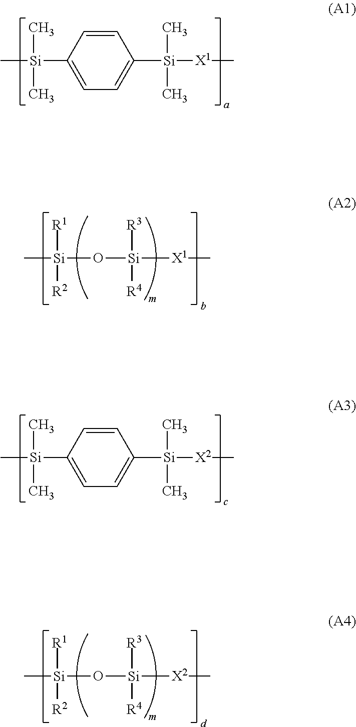
wherein R¹ to R⁴ are each independently a hydrocarbyl group that has 1 to 20 carbon atoms and may contain a heteroatom, m is each independently an integer of 1 to 600, and when m is an integer of 2 or more, R³s may be identical with or different from each other, and R⁴s may be identical with or different from each other, a, b, c, and d are numbers satisfying 0<a<1, 0<b<1, 0≤c<1, 0≤d<1, and a+b+c+d=1, X¹ is a divalent group having formula (X1), and X² is a divalent group having formula (X2); 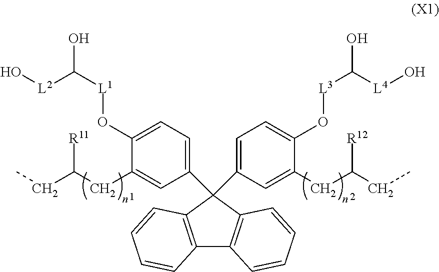
wherein n¹ and n² are each independently an integer of 1 to 7, R¹¹ and R¹² are each independently a hydrogen atom or a methyl group, L¹ to L⁴ are each independently a saturated hydrocarbylene group having 1 to 15 carbon atoms, a part of —CH₂— of the saturated hydrocarbylene groups may be substituted with —O—, —S—, —SO₂—, —CO—, or —CONH—, and a part or all of hydrogen atoms of the saturated hydrocarbylene groups may be substituted with a hydroxy group, and a broken line designates a bond; and 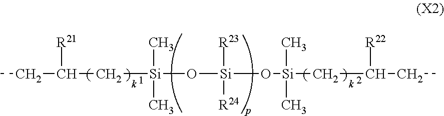
wherein R²¹ and R²² are each independently a hydrogen atom or a methyl group, R²³ and R²⁴ are each independently a hydrocarbyl group having 1 to 8 carbon atoms, k¹ and k² are each independently an integer of 0 to 7, p is an integer of 0 to 600, and a broken line designates a bond.

3. The photosensitive resin composition according to claim 2, wherein all of L¹, L², L³, and L⁴ have 1 carbon atom.

4. The photosensitive resin composition according to claim 1, wherein the content of the compound as component (B) is 1 to 50 parts by weight per 100 parts by weight of component (A).

5. The photosensitive resin composition according to claim 1, further comprising (D) a solvent.

6. A photosensitive resin coating obtained from the photosensitive resin composition according to claim 1.

7. A photosensitive dry film comprising a support film and the photosensitive resin coating according to claim 6 thereon.

8. A pattern forming process comprising the steps of:
(i) applying the photosensitive resin composition according to claim 1 onto a substrate to form a photosensitive resin coating thereon,
(ii) exposing the photosensitive resin coating to radiation, and
(iii) developing the exposed photosensitive resin coating in a developer to form a pattern of the resin coating.

9. The pattern forming process according to claim 8, further comprising (iv) post-curing the patterned photosensitive resin coating resulting from the development step at a temperature of 100 to 250° C.

10. A pattern forming process comprising the steps of:
(i′) using the photosensitive dry film according to claim 7 to form a photosensitive resin coating on a substrate,
(ii) exposing the photosensitive resin coating to radiation, and
(iii) developing the exposed photosensitive resin coating in a developer to form a pattern of the resin coating.

11. The pattern forming process according to claim 10, further comprising (iv) post-curing the patterned photosensitive resin coating resulting from the development step at a temperature of 100 to 250° C.

12. The photosensitive resin composition according to claim 1 which is a material adapted to form a coating for protecting electric and electronic parts.

13. The photosensitive resin composition according to claim 1 which is a material adapted to form a substrate-bonding coating for bonding two substrates.
